(19) United States
(12) Patent Application Publication
(10) Pub. No.: US 2025/0157800 A1
(43) Pub. Date: May 15, 2025

(54) Oxidation-Reduction Adjustable Plasma

(71) Applicant: Applied Materials, Inc., Santa Clara, CA (US)

(72) Inventors: Banqiu WU, San Jose, CA (US); Khalid MAKHAMREH, Los Gatos, CA (US); Eliyahu Shlomo DAGAN, Sunnyvale, CA (US)

(21) Appl. No.: 18/388,211

(22) Filed: Nov. 9, 2023

(51) Int. Cl. H01J 37/32

(52) U.S. Cl. CPC H01J 37/32972; H01J 37/32357; H01J 37/32422; H01J 37/32449; H01J 2237/24585

(57) ABSTRACT

Methods and systems for treating a photomask are provided, which include producing a plasma comprising a radical species; measuring an optical emission spectrum of the radical species; and contacting the photomask with the radical species in a process chamber to remove a contaminant from a surface or to modify the surface of the photomask, wherein a presence of the radical species is controlled based at least in part on the measured optical emission spectrum.

### FIELD

Embodiments of the present disclosure generally relate to a method and system for cleaning or otherwise processing a photomask.

### BACKGROUND

Current plasma-based cleaning and processing of substrates, such as photomasks, may use water vapor or oxygen to form radical species which contact the photomask to be processed. However, the inventors have observed that photomasks incur damage resultant from such processing. For example, cleaning of an EUV photomask having a ruthenium capping layer via plasma-based cleaning methods utilizing water vapor and/or oxygen has been observed to damage the ruthenium capping layer.

### SUMMARY

Methods and systems for treating a photomask are provided herein. In embodiments, a method of treating a photomask, comprises producing a plasma comprising a radical species; measuring an optical emission spectrum of the radical species; and contacting the photomask with the radical species in a process chamber to remove a contaminant from a surface, and/or to modify the surface of the photomask; wherein an amount of the radical species is controlled based at least in part on the measured optical emission spectrum.

In embodiments, a substrate processing system comprises a process chamber; a plasma source to produce a radical species to remove a contaminant from a surface of a photomask in the process chamber, and/or to modify the surface of the photomask; and an optical emission spectrometer configured to measure an optical emission spectrum of the radical species; wherein the system is configured to control an amount of the radical species based at least in part on the measured optical emission spectrum.

In embodiments, a non-transitory computer readable medium having instructions stored thereon which when executed cause a substrate processing system to perform a method of treating a photomask comprising producing a plasma comprising a radical species; measuring an optical emission spectrum of the radical species; and contacting the photomask with the radical species in a process chamber to remove a contaminant from a surface of the photomask and/or to modify the surface of the photomask; wherein a presence of the radical species is controlled based at least in part on the measured optical emission spectrum.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flowchart depicting a method of treating a photomask according to embodiments disclosed herein.

FIG. 2 depicts a substrate processing system according to embodiments disclosed herein.

FIG. 3 is an optical emission spectrum showing oxygen radicals as a dominant species according to embodiments disclosed herein.

FIG. 4 is an optical emission spectrum showing hydroxyl radicals as a dominant species according to embodiments disclosed herein.

FIG. 5 is an optical emission spectrum showing hydrogen radicals as a dominate species according to embodiments disclosed herein.

FIG. 6 is an optical emission spectrum showing a combination of oxygen radicals, hydroxyl radicals, and hydrogen radicals as the dominate species according to embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

A method and system for cleaning or otherwise processing a photomask surface in which damage to the photomask is minimized or eliminated is disclosed herein, wherein the method includes adjusting the oxidation-reduction capabilities of the plasma.

Current plasma-based cleaning methods and systems use water vapor and/or oxygen without monitoring and controlling of the reactive agents. Embodiments disclosed herein monitor and control the reaction agents to minimize damage introduced by the cleaning process.

In embodiments, the cleaning or otherwise processing of the photomask is controlled to minimize damage by controlling the oxidation-reduction properties or characteristics of the radicals produced via a plasma. In embodiments, a method of treating a photomask comprises producing a plasma comprising a radical species; measuring an optical emission spectrum of the radical species; contacting the photomask with the radical species in a process chamber to remove a contaminant from a surface, and/or to modify the surface of the photomask; wherein a presence of the radical species is controlled based at least in part on the measured optical emission spectrum.

In embodiments, the optical emission spectrum of the radical species is measured in a plasma processing chamber. In embodiments, the plasma is generated in an inductively coupled plasma, a toroidal plasma, or a combination thereof. In embodiments, the plasma is produced within a remote plasma source separated from the process chamber by an ion filter configured to prevent at least a portion of a charged species present within the remote plasma source from entering the process chamber.

In embodiments, a presence of a first radical species is controlled relative to a presence of a second radical species via controlling a composition of gas present in a plasma source, an amount of at least one gas directed into the plasma source, controlling a process chamber pressure, controlling a plasma source pressure, controlling a plasma power, or a combination thereof. In embodiments, the radical species is produced from diatomic oxygen, water vapor, or a mixture thereof, and the radical species comprise a combination of hydroxyl radicals, hydrogen radicals, and oxygen radicals, each present in the process chamber in an amount relative to one another suitable to remove an organic contaminant produced by formation of an EUV mask. In embodiments, diatomic oxygen is present within a plasma source at less than or equal to about 30% by volume, based on a total volume of diatomic oxygen and water vapor present within the plasma source.

In embodiments, the measured optical emission spectrum comprises an absorption at about 309 nm for hydroxyl radicals having a first area, an absorption at about 656 nm for hydrogen radicals having a second area, and an absorption at about 777 nm for oxygen radicals having a third area, wherein the second area is greater than the first area, and the second area is greater than the third area in the measured spectrum. In embodiments, a temperature of the photomask is less than or equal to about 150° C.

In embodiments, a substrate processing system comprises a plasma source coupled to a process chamber, configured to contact a photomask in the process chamber with radical species produced within the plasma source to remove a contaminant from a surface of the photomask and/or to modify the surface of the photomask; and an optical emission spectrometer coupled to the plasma source, the process chamber, or both, configured to measure an optical emission spectrum of the radical species produced within the plasma source and determine a presence of the radical species within the plasma source, the process chamber, or both, based at least in part on the measured optical emission spectrum; wherein the system is configured to control an amount of one or more radical species present within the process chamber based at least in part on the measured optical emission spectrum.

In embodiments, the system is configured to measure the optical emission spectrum of the radical species in the process chamber. In embodiments, the system is configured to measure the optical emission spectrum of the radical species in the plasma source.

In embodiments, the plasma source is an inductively coupled plasma source, a toroidal plasma source, or a combination thereof. In embodiments, the plasma source is separated from the process chamber by an ion filter configured to prevent at least a portion of a charged species present within the plasma source from entering the process chamber.

In embodiments, the system is configured to control a presence of a first radical species relative to a presence of a second radical species via controlling a composition of gas present in the plasma source, an amount of at least one gas directed into the plasma source; a process chamber pressure; a plasma source pressure; a plasma power; or a combination thereof, based at least in part on the measured optical emission spectrum of the radical species.

In embodiments, the system is configured to produce the radical species from diatomic oxygen, water vapor, or a mixture thereof, and to produce radical species comprising a combination of hydroxyl radicals, hydrogen radicals, and oxygen radicals within the process chamber in an amount relative to one another suitable to remove an organic contaminant present on a photomask comprising an EUV photomask comprising a ruthenium capping layer. In embodiments, the system is configured to maintain a temperature of the photomask at less than or equal to about 150° C. In embodiments, the photomask is maintained at a temperature from about 10° C. to less than or equal to about 150° C.

In embodiments, a non-transitory computer readable medium, having instructions stored thereon which, when executed, causes a substrate processing system according to one or more embodiments disclosed herein, to perform a method according to one or more embodiments disclosed herein.

The inventors have discovered that oxygen radicals have stronger oxidizing characteristics when compared to hydroxyl radicals, and efficiently remove organic contaminants from photomasks. However, the presence of oxygen radicals tends to oxidize the ruthenium capping layer present on EUV photomasks, having a detrimental effect. Likewise, radicals produced from water, mainly hydroxyl radicals and hydrogen radicals, do not negatively affect the ruthenium capping layer of EUV photomasks, but lack the oxidizing characteristics to remove all of the organic species present on photomasks in an efficient manner.

Embodiments disclosed herein utilize an optical emission spectrometer to monitor the presence of the oxidizing agents such as oxygen radicals and hydroxyl radicals, and the presence of reducing agents such as atomic hydrogen radicals. By adjusting and controlling the relative proportions of the various radical species present, based on the relative area of the absorptions present in the measured optical emission spectrum, the composition can be controlled to balance the oxidation and reduction characteristics of the radicals contacting the photomask to efficiently remove organic contaminants present on the surface while minimizing any damage, e.g., oxidation, of the ruthenium capping layer or other attribute present on the photomask.

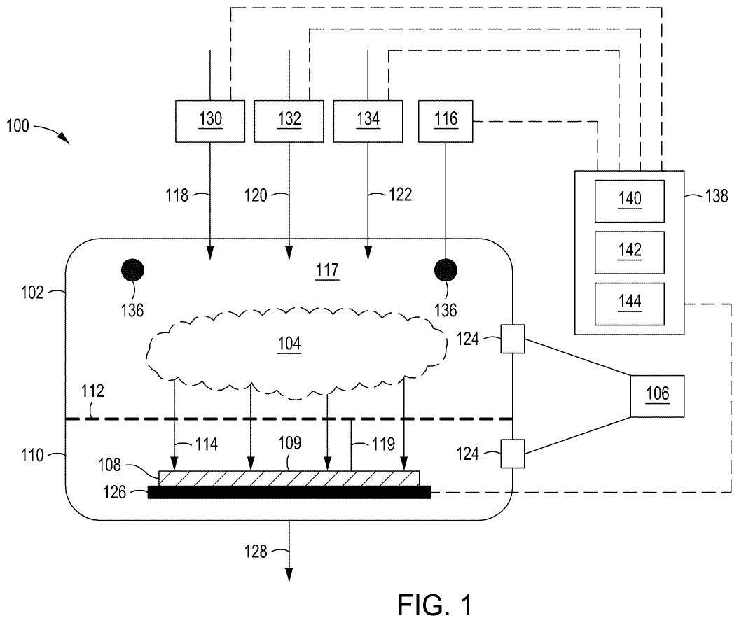

FIG. 1 depicts a substrate processing system 100 according to embodiments disclosed herein comprising a plasma source 102 coupled to a process chamber 110, configured to contact a photomask 108 disposed on a substrate support 126 in the process chamber 110 with radical species 114 produced within the plasma source 102, i.e., within plasma 104. In embodiments, contact of the radical species 114 with the surface 109 of the photomask 108 remove contaminants from surface 109 of the photomask 108. In embodiments, contact of the radical species 114 with the surface 109 of the photomask 108 may etch or otherwise process surface 109 of the photomask 108.

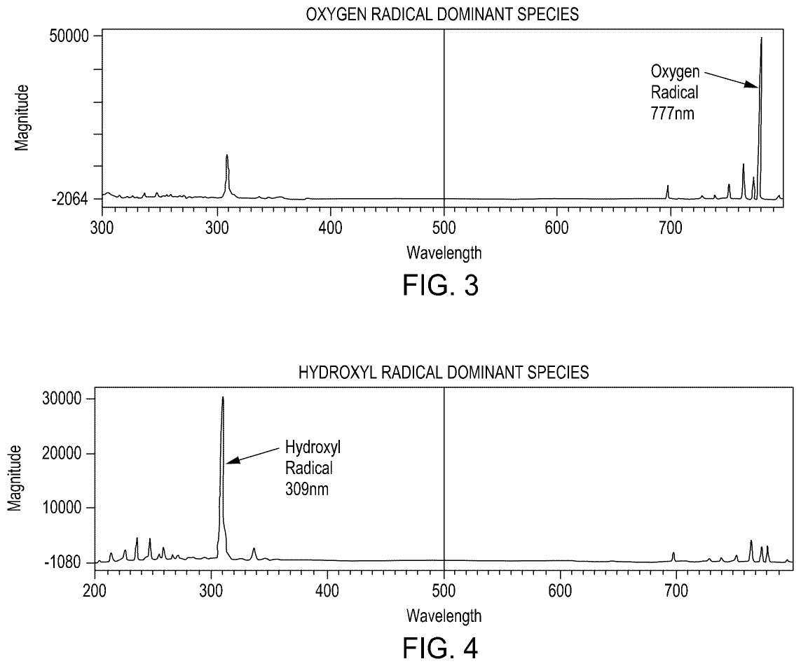

Substrate processing system 100 further comprises an optical emission spectrometer 106 coupled to the plasma source 102, to the process chamber 110, or both, e.g., via a window, a fiber optic, an optical bridge, or the like, represented as 124. The optical emission spectrometer 106 is configured to measure an optical emission spectrum of the radical species 114 produced within the plasma source 102 and determine a presence of the radical species 114 within the plasma source 102, the process chamber 110, or both, based at least in part on the measured optical emission spectrum. Examples of optical emission spectra of the radical species measured by the optical emission spectrometer 106 are provided in FIGS. 3, 4, 5, and 6 as discussed herein.

In embodiments, the system is configured to produce a plasma 104 is an inductively coupled plasma, e.g., via RF inductors 136. In embodiments, the plasma 104 is a toroidal plasma (not shown). In embodiments, the system comprises one or more system controllers 138 configured to control an amount of one or more radical species 114 present within the process chamber 110 based at least in part on the measured optical emission spectrum. The system controller 138 may control the operation of the system using direct control of the plasma source 102, the process chamber 110, components utilized to control the amount and composition of the gas directed into the plasma source such as the various flow meters 130, 132, 134 discussed herein, the optical emission spectrometer 106, the RF generator 116, and any additional control or monitoring components or systems. In the alternative, the system controller 138 may control other control systems associated with the various components. In operation, the system controller 138 enables data collection and feedback from the process chamber, the plasma source, the optical emission spectrometer, and other associated systems to optimize performance of the system 100. The system controller 138 generally includes a central processing unit (CPU) 140, a memory 142, and a support circuit 144. The CPU 140 may be any form of a general-purpose computer processor that can be used in an industrial setting. The support circuit 144 is conventionally coupled to the CPU 140 and may comprise a cache, clock circuits, input/output subsystems, power supplies, and the like. Software routines, such as a method as described above may be stored in the memory 142 and, when executed by the CPU 140, transform the CPU 140 into a specific purpose computer (system controller) 138. The software routines may also be stored and/or executed by a second controller (not shown) that is located remotely from the system 100.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

In embodiments, the plasma is produced within a remote plasma source such as plasma source 102 as depicted in FIG. 1, which is commonly referred to in the art as a downstream plasma source, and which is separated from the process chamber 110 by an ion filter 112 and configured to prevent at least a portion of a charged species present within the remote plasma source (e.g., plasma source 102) from entering the process chamber 110. Suitable examples of ion filters include screens and/or the like, maintained at a potential which prevent charged species present in the plasma 104 from entering the process chamber 110, but which allow the radical species 114, which are electrically neutral, to enter the process chamber 110 and contact the surface 109 of the photomask 108. In other embodiments, the plasma is produced in-situ with the photomask, i.e., wherein the plasma source is located within the process chamber.

Examples of such radical species include atomic hydrogen H·, hydroxyl radicals OH·, atomic oxygen O·, atomic halogens such as atomic chlorine Cl·, atomic bromine Br·, and the like, phosphorus centered radicals R₂—P·, and the like. In embodiments, a distance 119 between the ion filter 112 and the surface 109 of the photomask 108, or in the alternative the substrate support 126, is less than or equal to about 50 mm, or is greater or equal to about 5 mm and less than about 50 mm, or greater than or equal to about 10 mm and less than about 25 mm.

In embodiments, a presence of a first radical species is controlled relative to a presence of a second radical species. In embodiments, the system is controlled such that both the first and the second radical species are present in the process chamber. In other embodiments, the system may be controlled to prevent one of the two radical species from being present in the process chamber.

In embodiments, the presence of radical species 114 within the process chamber 110 is controlled via controlling a composition of the gas 117 present in the plasma source 102. In embodiments, the presence of the radical species 114 within the process chamber 110 is controlled by controlling an amount of at least one gas e.g., 118, 120, and/or 122 directed into the plasma source 102, e.g., via control valves or metering devices such as flow meters 130, 132 and 134, respectively. In embodiments, a flow rate of each gas into the plasma source 102 is less than or equal to about 5 liters per minute, or from about 0.5 liters per minute to about 4.5 liters per minute for at least one of the gases. In embodiments, the presence of radical species 114 within the process chamber 110 is controlled via controlling the pressure of the process chamber. In embodiments, the process chamber is maintained at less than about 5 Torr, or from about 0.1 Torr to about 2 Torr. In embodiments, the presence of radical species 114 within the process chamber 110 is controlled via controlling the pressure of the plasma source. In embodiments, the plasma source is maintained at less than about 5 Torr, or from about 0.7 Torr to about 1 Torr. In embodiments, the gas is vented from the process chamber via outlet 128.

In embodiments, the presence of radical species 114 within the process chamber 110 is controlled via controlling the plasma power, e.g., the RF power used to produce the plasma. In embodiments, the plasma power is greater than or equal to about 1 KW. In embodiments, the plasma power is from about 1 kW to about 4 KW, or from about 2 kW to about 3.5 kW.

In embodiments, the radical species are produced from diatomic oxygen, water vapor, or a mixture thereof, and comprise a combination of hydroxyl radicals, hydrogen radicals, and oxygen radicals, each present in the process chamber in an amount relative to one another suitable to remove an organic contaminant produced by formation of an EUV mask without damaging the ruthenium capping layer, e.g., without rendering the ruthenium capping layer present therein ineffective for an intended purpose for which the ruthenium capping layer is present.

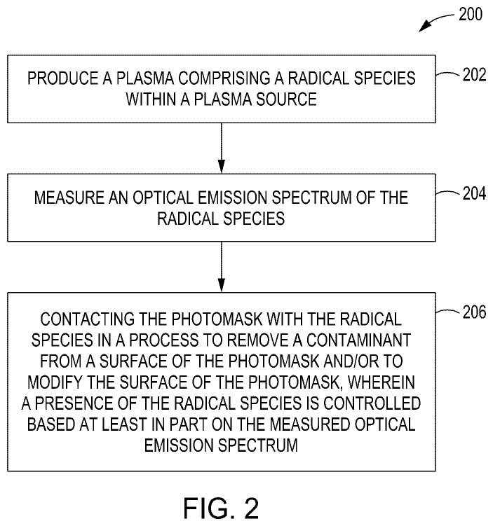

FIG. 2 depicts a method 200 of treating a photomask according to embodiments disclosed herein. In embodiments, method 200 comprises producing a plasma comprising a radical species within a plasma source (block 202); measuring an optical emission spectrum of the radical species (block 204); and contacting the photomask with the radical species in a process chamber to remove a contaminant from a surface of the photomask and/or to modify the surface of the photomask, wherein the photomask and/or a presence of the radical species is controlled based at least in part on the measured optical emission spectrum (block 206). In embodiments, the presence of the radical species is determined in real time while contacting the photomask. However, in alternative embodiments, the various settings of the system may be determined based on the measured optical emission spectrum, and the photomask may be processed based at least in part on the previously determined settings without real-time monitoring of the optical emission spectrum.

In embodiments, a presence of a first radical species is controlled relative to a presence of a second radical species via controlling a composition of gas present in a plasma source, an amount of at least one gas directed into the plasma source, controlling a process chamber pressure, controlling a plasma source pressure, controlling a plasma power, or a combination thereof. In embodiments, diatomic oxygen is present within the plasma source at less than or equal to about 30% by volume, or less than or equal to about 25% by volume, or less than or equal to about 10% by volume, based on a total volume of diatomic oxygen and water vapor present within the plasma source. In embodiments, diatomic oxygen is not added to the plasma source. In embodiments, water vapor is present within the plasma source at from essentially 100% water vapor by volume to about 70% by volume, based on the pressure and temperature of plasma source. In embodiments, the plasma source further includes a diluent such as argon.

FIG. 3 depicts an optical emission spectrum comprising oxygen radicals as the dominant species as indicated by the absorption at 777 nm, which forms a “base peak” having the largest area in the measured spectrum. The presence of all other absorption peaks are determined based on their area as a percentage of the base peak.

FIG. 4 depicts an optical emission spectrum comprising hydroxyl radicals produced from water vapor as the dominant species as indicated by the absorption at 309 nm forming the base peak having the largest area in the measured spectrum.

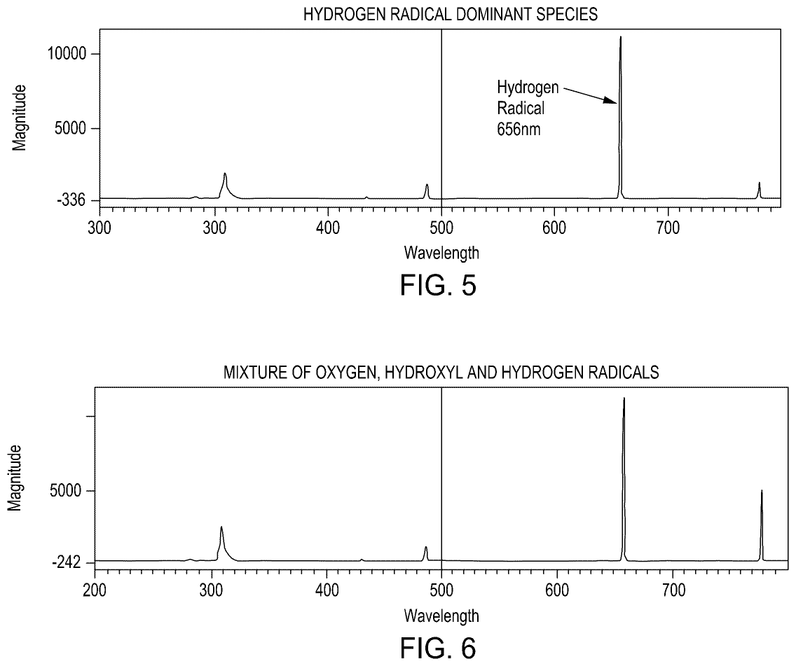

FIG. 5 depicts an optical emission spectrum comprising hydrogen radicals produced from water vapor as the dominant species as indicated by the absorption at 656 nm forming the base peak having the largest area in the measured spectrum.

FIG. 6 depicts an optical emission spectrum comprising a mixture of oxygen radicals (777 nm), hydroxyl radicals (309 nm), and hydrogen radicals (656 nm), produced from a combination of oxygen and water vapor present in the plasma source according to embodiments disclosed herein, wherein the hydrogen radicals at 656 nm and the oxygen radicals at 777 nm are present as the main species.

In embodiments, the measured optical emission spectrum comprises an absorption at about 309 nm for hydroxyl radicals having a first area, an absorption at about 656 nm for hydrogen radicals having a second area, and an absorption at about 777 nm for oxygen radicals having a third area, wherein the second area is greater than the first area, and greater than the third area in the measured spectrum.

While the foregoing is directed to embodiments of the present disclosure, other and further embodiments of the disclosure may be devised without departing from the basic scope thereof.

1. A method of treating a photomask, comprising:
producing a plasma comprising a radical species;
measuring an optical emission spectrum of the radical species; and
contacting the photomask with the radical species in a process chamber to remove a contaminant from a surface, and/or to modify the surface of the photomask;
wherein an amount of the radical species is controlled based at least in part on the measured optical emission spectrum.

2. The method of claim 1, wherein the optical emission spectrum of the radical species is measured in the process chamber.

3. The method of claim 1, wherein the optical emission spectrum of the radical species is measured in a plasma source.

4. The method of claim 1, wherein the plasma is an inductively coupled plasma, a toroidal plasma, or a combination thereof.

5. The method of claim 1, wherein the plasma is produced within a remote plasma source separated from the process chamber by an ion filter configured to prevent at least a portion of a charged species present within the remote plasma source from entering the process chamber.

6. The method of claim 1, wherein a presence of a first radical species is controlled relative to a presence of a second radical species via controlling a composition of gas present in a plasma source, an amount of at least one gas directed into the plasma source, controlling a process chamber pressure, controlling a plasma source pressure, controlling a plasma power, or a combination thereof.

7. The method of claim 1, wherein the radical species is produced from diatomic oxygen, water vapor, or a mixture thereof, and wherein the radical species comprise a combination of hydroxyl radicals, hydrogen radicals, and oxygen radicals, each present in the process chamber in an amount relative to one another suitable to remove an organic contaminant produced by formation of an EUV photomask.

8. The method of claim 7, wherein diatomic oxygen is present within a plasma source at less than or equal to about 30% by volume, based on a total volume of diatomic oxygen and water vapor present within the plasma source.

9. The method of claim 7, wherein the measured optical emission spectrum comprises an absorption at about 309 nm for hydroxyl radicals having a first area, an absorption at about 656 nm for hydrogen radicals having a second area, and an absorption at about 777 nm for oxygen radicals having a third area, wherein the second area is greater than the first area, and greater than the third area in the measured optical emission spectrum.

10. The method of claim 1, wherein a temperature of the photomask is less than or equal to about 150° C.

11. A substrate processing system, comprising:
a process chamber;
a plasma source to produce a radical species to remove a contaminant from a surface of a photomask in the process chamber, and/or to modify the surface of the photomask; and
an optical emission spectrometer configured to measure an optical emission spectrum of the radical species;
wherein the system is configured to control an amount of the radical species based at least in part on the measured optical emission spectrum.

12. The system of claim 11, configured to measure the optical emission spectrum of the radical species in the process chamber.

13. The system of claim 11, configured to measure the optical emission spectrum of the radical species in the plasma source.

14. The system of claim 11, wherein the plasma source is an inductively coupled plasma source, a toroidal plasma source, or a combination thereof.

15. The system of claim 11, wherein the plasma source is separated from the process chamber by an ion filter configured to prevent at least a portion of a charged species present within the plasma source from entering the process chamber.

16. The system of claim 15, wherein a substrate support is separated from the ion filter by a distance of less than or equal to about 50 mm.

17. The system of claim 11, configured to control an amount of a first radical species relative to an amount of a second radical species via controlling:
a composition of gas present in the plasma source;
an amount of at least one gas directed into the plasma source;
a process chamber pressure;
a plasma source pressure;
a plasma power; or
a combination thereof, based at least in part on the measured optical emission spectrum of the radical species.

18. The system of claim 11, configured to produce the radical species from diatomic oxygen, water vapor, or a mixture thereof, and to produce radical species comprising a combination of hydroxyl radicals, hydrogen radicals, and oxygen radicals within the process chamber in an amount relative to one another suitable to remove an organic contaminant present on a substrate comprising an EUV photomask comprising a ruthenium capping layer.

19. The system of claim 11, configured to maintain a temperature of the photomask at less than or equal to about 150° C.

20. A non-transitory computer readable medium, having instructions stored thereon which, when executed, cause a substrate processing system to perform a method of treating a photomask, comprising:
producing a plasma comprising a radical species;
measuring an optical emission spectrum of the radical species; and
contacting the photomask with the radical species in a process chamber to remove a contaminant from a surface of the photomask and/or to modify the surface of the photomask;
wherein an amount of the radical species is controlled based at least in part on the measured optical emission spectrum.
